(19) United States
(12) Patent Application Publication
(10) Pub. No.: US 2018/0294202 A1
(43) Pub. Date: Oct. 11, 2018

(54) CHIP PACKAGE STRUCTURE AND MANUFACTURING METHOD THEREOF

(71) Applicants: Industrial Technology Research Institute, Hsinchu (TW); Intellectual Property Innovation Corporation, Hsinchu (TW)

(72) Inventors: Wei-Yuan Cheng, Hsinchu County (TW); Cheng-Chung Lee, Hsinchu City (TW); Shau-Fei Cheng, Pingtung County (TW); Wen-Lung Chen, Miaoli County (TW)

(73) Assignees: Industrial Technology Research Institute, Hsinchu (TW); Intellectual Property Innovation Corporation, Hsinchu (TW)

(21) Appl. No.: 15/856,069

(22) Filed: Dec. 28, 2017

Related U.S. Application Data
(60) Provisional application No. 62/483,961, filed on Apr. 11, 2017.

(30) Foreign Application Priority Data
Nov. 22, 2017 (TW) 106140493

(51) Int. Cl. H01L 23/31; H01L 23/538; H01L 23/60; H01L 23/00; H01L 21/48; H01L 21/56; H01L 21/78

(52) U.S. Cl. CPC H01L 23/3135; H01L 2924/3511; H01L 23/5383; H01L 23/5386; H01L 23/60; H01L 23/562; H01L 23/564; H01L 21/4857; H01L 21/4853; H01L 21/561; H01L 21/565; H01L 21/78; H01L 24/20; H01L 24/19; H01L 24/97; H01L 2224/214; H01L 2924/302; H01L 23/5389

(57) ABSTRACT

A chip package structure and a manufacturing method thereof are provided. The chip package structure includes a frame disposed around a chip, a filling material filled in the space between the chip and the frame, and a protection layer covering the chip, the frame, and the filling material. The Young's modulus of the filling material is respectively smaller than the Young's modulus of the chip, the Young's modulus of the frame, and the Young's modulus of the protection layer.

### CROSS-REFERENCE TO RELATED APPLICATION

This application claims the priority benefit of U.S. provisional application Ser No. 62/483,961, filed on Apr. 11, 2017 and Taiwan application serial no. 106140493, filed on Nov. 22, 2017. The entirety of each of the above-mentioned patent application is hereby incorporated by reference herein and made a part of this specification.

### TECHNICAL FIELD

The disclosure relates to a package structure, and also relates to a chip package structure and a manufacturing method thereof.

### BACKGROUND

Semiconductor packaging methods are divided into ceramic packaging and resin packaging. Ceramic packaging has good moisture resistance and long life but high cost; and resin packaging has low cost, large yield, and performance that meets market demand, and is therefore currently the main semiconductor packaging method. The polymer material for regular resin packaging includes, for instance, epoxy resin, polyimide (PI), phenolic resin, and silicone resin. Among these four materials, other than power devices with large heat dissipation that need to adopt silicone resin with higher cost, an epoxy resin is used for the most part. The epoxy resin used in a packaging adhesive includes, for instance, bisphenol-A, novolac epoxy resin, cyclicaliphatic epoxy resin, and epoxydized butadiene. Currently, o-creso novolac epoxy resin (CNE) is mainly used as the semiconductor packaging material.

However, in a panel-level packaging process, after molding, the coefficient of thermal expansion of the molding compound is different from the coefficient of thermal expansion of the chip and the coefficient of thermal expansion of the substrate, and therefore warpage of the package readily occurs, such that the issue of poor reliability, resulting from subsequent difficult removal process, occurs. Moreover, if a molding compound with high viscosity is used, then the issue of the molding compound located at a side of the chip readily peeling, due to thermal deformation and residual stress caused by the packaging process, occurs.

### SUMMARY

An embodiment of the disclosure provides a chip package structure including a redistribution layer, a chip, a frame, a filling material, and a protection layer. The redistribution layer has an upper surface. The chip is disposed on the upper surface of the redistribution layer and electrically connected to the redistribution layer. The frame is disposed on the upper surface of the redistribution layer and surrounds the chip. The filling material is disposed on the upper surface of the redistribution layer and located between the frame and the chip. The protection layer covers the chip, the frame, and the filling material. The Young's modulus of the filling material is respectively smaller than the Young's modulus of the chip, the Young's modulus of the frame, and the Young's modulus of the protection layer, as well as the filling thickness of the filling material is at least 1.5 times the thickness of the protection layer.

Another embodiment of the disclosure provides a chip package structure including a redistribution layer, a chip, a frame, a filling material, and a protection layer. The redistribution layer has an upper surface. The chip is disposed on the upper surface of the redistribution layer and electrically connected to the redistribution layer. The frame is disposed on the upper surface of the redistribution layer and surrounds the chip. The filling material is disposed on the upper surface of the redistribution layer and located between the frame and the chip. The viscosity of the filling material is 2,000-20,000 mPa·s at 25° C. The protection layer covers the chip, the frame, and the filling material. The Young's modulus of the filling material is respectively smaller than the Young's modulus of the chip, the Young's modulus of the frame, and the Young's modulus of the protection layer.

Another embodiment of the disclosure provides a manufacturing method of a chip package structure includes the following. A redistribution layer is formed. A plurality of chips are bonded on the redistribution layer. A plurality of frames are formed on the redistribution layer to respectively surround at least one of the chips. A filling material is filled in a space between the frames and the chips. A protection layer is formed on the chips, the frames, and the filling material, wherein a Young's modulus of the filling material is respectively smaller than a Young's modulus of the chips, a Young's modulus of the frames, and a Young's modulus of the protection layer. A singulation process id performed.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIGS. 1A to 1C are schematics of a chip package structure according to an embodiment of the disclosure, wherein FIG. 1A is a top view of the configuration of a chip and a frame and FIGS. 1B to 1C are cross-sectional structures of section line I-I′ in FIG. 1A.

FIGS. 2A to 2C are schematics of a chip package structure according to an embodiment of the disclosure, wherein FIG. 2A is a top view of the configuration of a chip and a frame and FIGS. 2B to 2C are cross-sectional structures of section line II-II′ in FIG. 2A.

FIG. 3A to FIG. 3H show top views of other possible configurations of the chips and the frames.

FIGS. 4A to 4E show cross sections of the structure in a manufacturing process of the chip package structure in FIG. 1B.

### DETAILED DESCRIPTION OF DISCLOSED EMBODIMENTS

An embodiment of the disclosure provides a chip package structure and a manufacturing method thereof. In the chip package structure, a frame structure is disposed around the chip, and then a filling material with lower Young's modulus and lower coefficient of thermal expansion (CTE) is filled between the chip and the frame structure.

In the following description, an exemplary structure of the chip package structure above and an exemplary manufacturing method thereof are described. To facilitate understanding of the embodiments, many technical details are provided below. Of course, these technical details are not a requirement for every embodiment. At the same time, some known structures or devices are only schematically shown in the figures to suitably simplify the contents of the figures.

### Chip Package Structure

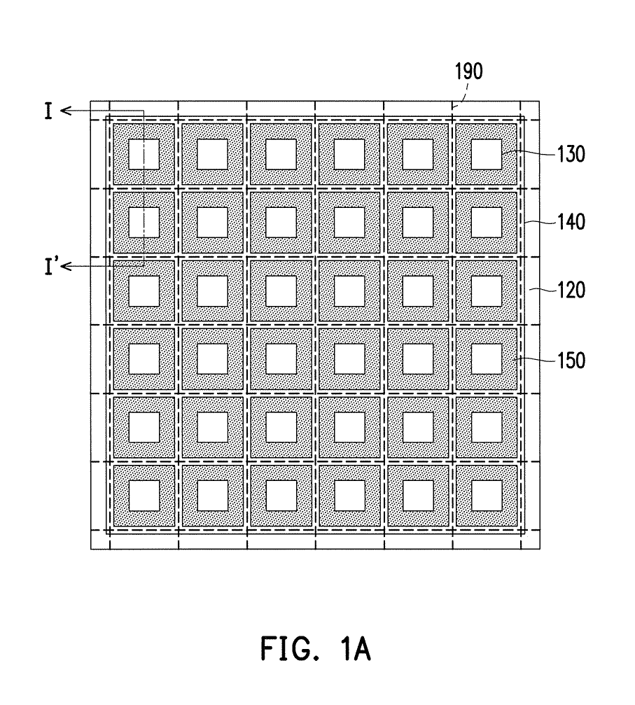

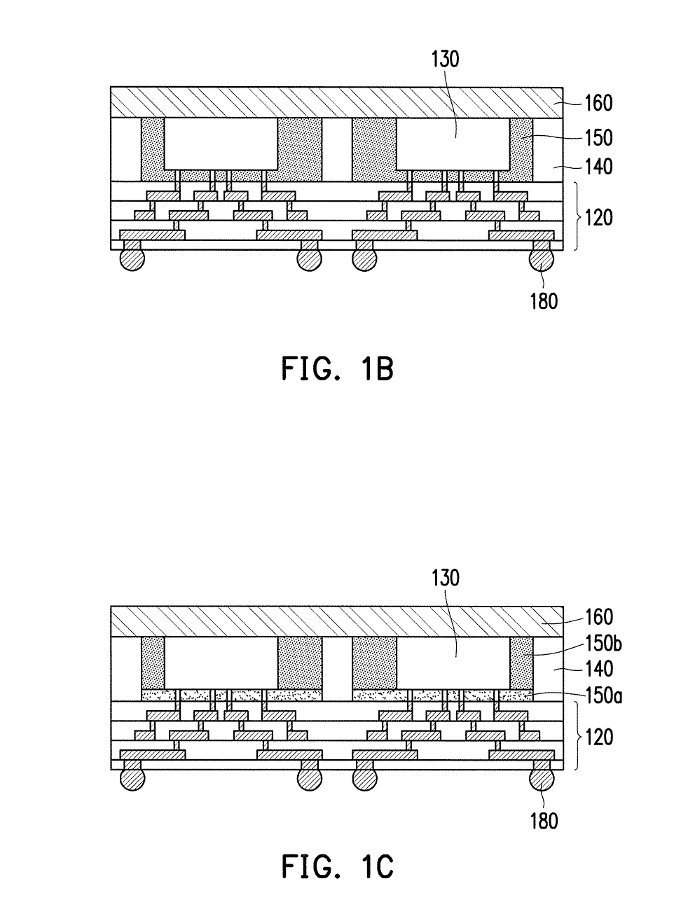

FIGS. 1A to 1C are schematics of a chip package structure according to an embodiment of the disclosure, wherein FIG. 1A is a top view of the configuration of a chip and a frame and FIGS. 1B to 1C are cross sections of section line I-I′ in FIG. 1A. Referring to FIGS. 1A to 1C, a chip package structure includes a redistribution layer (RDL) 120, a chip 130, a frame 140, a filling material 150, and a protection layer 160.

The RDL 120 has a bottom surface and an upper surface opposite to each other. A plurality of chips 130 are disposed on the upper surface of the RDL 120, and the chips 130 are electrically connected to the RDL 120 via contacts on the upper surface of the RDL 120. A plurality of frames 140 are disposed on the upper surface of the RDL 120. The frames 140 are disposed on periphery of each of the chips 130, and each of the frames 140 surrounds the chips 130 but is not in direct contact with the chips 130. Each of the frames 140 is connected to one another to integrally form a continuous structure similar to a checkerboard. After the chip package structure is completed, sawing lanes 190 can be disposed along the position of each of the frames 140, and the linked overall frames 140 can be cut in a subsequent process as needed to separate the chips 130.

In FIG. 1B, the RDL 120 includes a plurality of dielectric layers and a plurality of conductive layers that are alternately stacked, and can be, for instance, a 4-layer or 8-layer structure. The thickness of the RDL 120 structure is, for instance, about 30 μm to 60 μm, and the Young's modulus thereof is about 6 GPa. A plurality of bumps 180 is disposed on the side of the RDL 120 opposite to the side on which the chips 130 are disposed, i.e., the bottom surface of the RDL 120. The bumps 180 are electrically connected to the RDL 120 via contact pads on the bottom surface of the RDL 120. Since the frames 140 are disposed around the chips 130 to surround the chips 130, the filling material 150 is filled inside the frames 140 and between the frames 140 and the chips 130, and completely fill the space defined by the protection layer 160, the frames 140, the chips 130, and the RDL 120. In other words, the filling material 150 is located between the protection layer 160, the frames 140, the chips 130, and the RDL 120. The protection layer 160 is disposed on the chips 130, the frames 140, and the filling material 150.

In FIG. 1B, the heights of the frames 140 and the filling material 150 can be the same as that of the chips 130 to provide a flatter bottom to the subsequent protection layer 160. According to an embodiment, the thickness of the chips 130 can be 5 μm to 200 μm or 100 μm to 150 μm. However, the height of the frames 140 is not particularly limited, and can be slightly lower than or higher than the height of the chips 130. Similarly, the height of the filling material 150 is mainly decided by the height of the frames 140 and can be substantially equal to or slightly lower than the height of the frames 140.

According to an embodiment, the thickness of the filling material 150 is at least 1.5 times the thickness of the protection layer, and can be, for instance, 1.5, 1.6, 1.7, 1.8, 1.9, or 2 times greater. According to an embodiment, the ratio of the maximum filling thickness of the filling material 150 and the thickness of the protection layer is 2 or more.

According to another embodiment, the Young's modulus of the filling material 150 is smaller than the Young's modulus of the chips 130, the Young's modulus of the frames 140, and the Young's modulus of the protection layer 160. That is, the hardness of the filling material 150 is smaller than the hardness of the chips 130, the hardness of the frames 140, and the hardness of the protection layer 160. According to another embodiment, the coefficient of thermal expansion of the filling material 150 is smaller than 30 ppm/° C., and the coefficient of thermal expansion of the filling material 150 is smaller than the coefficient of thermal expansion of the surrounding frames 140 and the coefficient of thermal expansion of the protection layer 160 on top. As a result, residual thermal stress can be effectively reduced by the overall design of the filling material 150 with the surrounding frames 140 and the protection layer 160 on top to solve the issue of package warping. According to another embodiment, the filling material 150 is formed by a filling adhesive material with low viscosity, and the frames 140 are formed by a curable adhesive material with higher viscosity (about 10,000 mPa·s to 500,000 mPa·s), wherein the viscosity of the filling adhesive material with low viscosity is lower than the viscosity of the curable adhesive material. For instance, the viscosity of the filling material 150 is 2,000 mPa·s to 20,000 mPa·s at 25° C.

According to some embodiments of the present application, the filling material 150 can be an insulating cured filling adhesive material formed by curing a filling adhesive material with low viscosity, and the filling adhesive material with low viscosity can be, for instance, a thermosetting epoxy material, polyacrylate, or polyimide. According to some embodiments of the present application, the filling material 150 can also be a non-conductive paste (NCP), a non-conductive film (NCF), or a fluid or semi-fluid underfill material.

In an embodiment of the present application, the filling material 150 with low viscosity and thermal expansion coefficient is used as a stress buffer layer located between the chips 130 and between the chips 130 and the frames 140 to solve the known issue of the molding compound, located at a side of the chips 130, readily peeling due to the side stress of the chips 130. In an embodiment of the present application, issues such as warping, delamination, peeling, or rupture are alleviated by reducing stress accumulated in a traditional molding process by the process of forming frames and filling a filling material and using suitable materials and structural designs, such as a retaining wall adhesive material, filling material, and molding material of protection layer.

According to some other embodiments of the present application, the material forming the frames 140 includes a metal, a ceramic, or a thermosetting epoxy resin, and the material of the protection layer 160 also includes a metal, a ceramic, or a thermosetting epoxy resin. According to some other embodiments of the present application, the frames 140 and the protection layer 160 can adopt the same material to effectively disperse the places affected by thermal stress and reduce the concentration of residual thermal stress. The frames 140 define the filling range and/or height (thickness) of the filling material 150, and the protection layer 160 can assist in heat conduction and providing functions such as blocking water vapor and oxygen and anti-static and anti-warping.

Among resin materials generally used as molding materials, a large quantity of silica particles is generally added as fillers to increase the hardness of the molding material to achieve the effect of protecting the chips. Therefore, when the frames 140, the filling material 150, and the protection layer 160 all adopt thermosetting epoxy resins similar to molding materials, the material of the filling material 150 almost does not contain fillers or contains a small quantity of fillers such that the Young's modulus of the filling material 150 (i.e., the hardness of the material) is lower. Compared to the adopted thermosetting epoxy resin similar to a molding material, the content of the fillers (such as silica particles) in the epoxy resin used for the filling material 150 is less than the content of the fillers (such as silica particles) in the frames 140 and the protection layer 160 materials. For instance, when silica particles are used as the fillers for the filling material 150, the average particle size of the silica particles can be about 0.6 μm to 10 μm, and the content of the silica particles can be about 50 wt % to 65 wt %.

In FIG. 1C, to more readily fill the filling material between the bottom of the chips 130 and the RDL 120, a first filling material 150a can be first filled between the bottom of the chips 130 and the RDL 120, and then a second filling material 150b is filled between the side wall of the chips 130 and the frames 140. In other words, the first filling material 150a is filled between the bottom (active surface) of the chips 130 and the upper surface of the RDL 120, and the second filling material 150b is filled between the side wall of the chips 130 and the frames 140. According to an embodiment of the present application, the material of the first filling material 150a and the material of the second filling material 150b are different. For instance, the material of the first filling material 150a does not contain fillers or contains less fillers and the material of the second filling material 150b contains more fillers. Alternatively, the viscosity of the first filling material 150a is smaller than the viscosity of the second filling material 150b, that is, the fluidity of the first filling material 150a is greater than the fluidity of the second filling material 150b. The space between the bottom of the chips 130 and the RDL 120 is smaller, and therefore a first filling material 150a having a smaller viscosity (i.e., greater fluidity) is needed to facilitate filling. Similarly, if the frames 140, the first filling material 150a, the second filling material 150b, and the protection layer 160 are all thermosetting epoxy resins, then the content of the silicone filler is least in the first filling material 150a, the content of the silicone filler in the second filling material 150b is more, and the content of the silicone filler in the protection layer 160 is most. The thickness of the first filling material 150a can be 45 μm to 60 μm, and the thickness of the second filling material 150b can be 60 μm to 250 μm. The other portions in FIG. 1C are similar to those of FIG. 1B and are therefore not repeated herein.

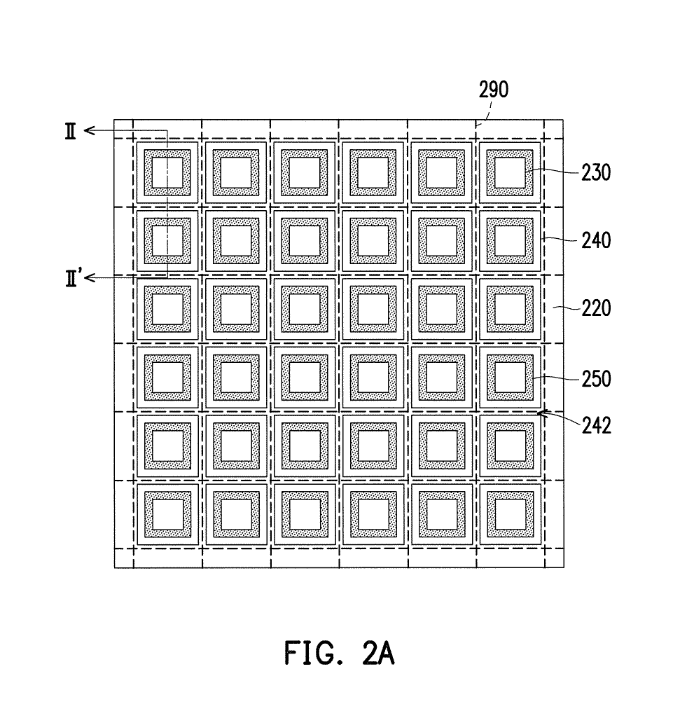

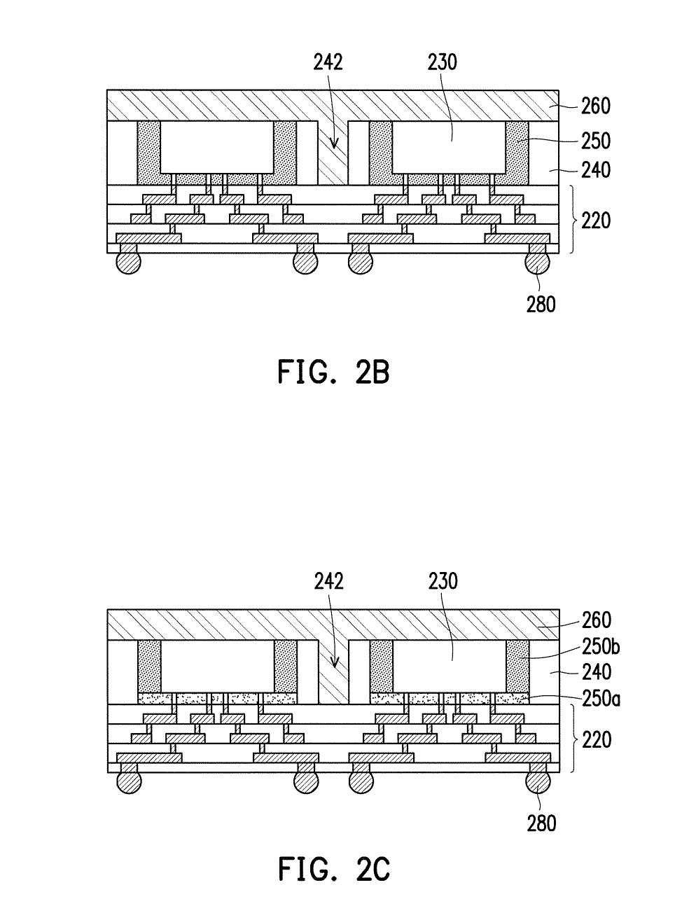

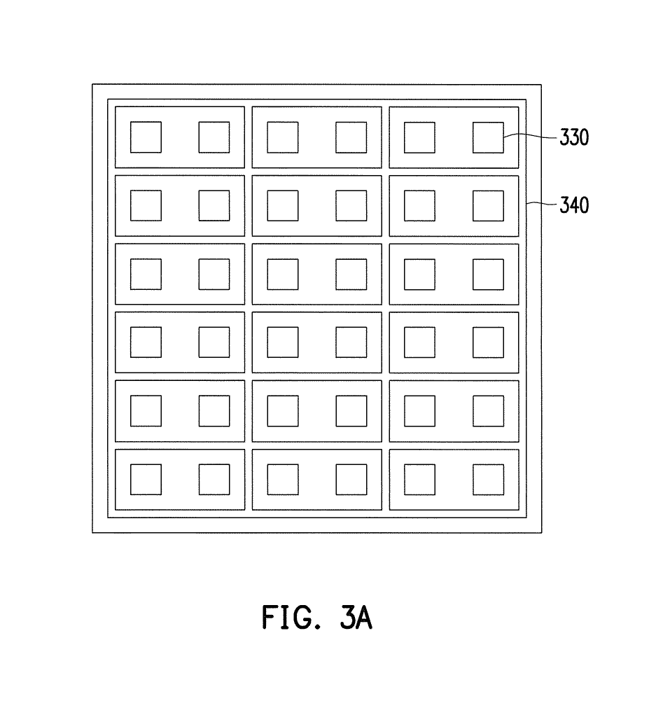

FIGS. 2A to 2C are schematics of a chip package structure according to an embodiment of the disclosure, wherein FIG. 2A is a top view of the configuration of a chip and a frame and FIGS. 2B to 2C are cross sections of the structures of section line II-II′ in FIG. 2A. Referring to FIGS. 2A to 2B, the configuration and relative position of the chip package structure thereof are similar to the configuration of the chip package structure shown in FIGS. 1A to 1B, except that the configurations of the frames and the protection layer are different. In FIGS. 2A to 2B, an independent frame 240 is disposed around each of the chips 230, and each of the frames 240 surrounds the chips 230 but are not in direct contact with the chips 230. The frames 240 are spaced apart and are not in contact with one another. Similarly, the RDL 220 includes a plurality of dielectric layers and a plurality of conductive layers that are alternately stacked, and the bumps 280 are disposed on the bottom surface of the RDL 220 and are electrically connected to the RDL 220 via contact pads on the bottom surface of the RDL 220. A filling material 250 is filled between the frames 240 and the chips 230. Since the frames 240 are disposed around the chips 230 to surround the chips 230 and the frames 240 are spaced apart and are not in contact with one another, a subsequently-formed protection layer 260 is disposed on the chips 230, the frames 240, and the filling material 250 and completely fill a space 242 between adjacent frames 240. The filling material 250 is filled inside the frames 240 and completely fill the space defined by the frames 240, the chips 230, the protection layer 260, and the RDL 220. In other words, the filling material 250 is located between the protection layer 260, the frames 240, the chips 230, and the RDL 220. After the chip package structure is complete, a desired scribe line 290 can be disposed along the space 242 between adjacent frames 240 to separate the chips 230 as needed.

In FIG. 2B, since the frames 240 are separate independent structures and are not the continuous structure of the frame 140 in FIG. 1B, two frames 240 are located between two adjacent chips 230, and the space 242 is formed between the two adjacent frames 240. The filling material 250 is filled in the space between the frames 240 and the chips 230 and in the space between the chips 230 and the RDL 220, but is not filled in the space 242 between adjacent frames 240. The protection layer 260 is disposed on the chips 230, the frames 240, and the filling material 250 and filled in the space 242 between adjacent frames 240. The other portions in FIG. 2B are similar to those of FIG. 1B and are not repeated herein.

Similar to FIG. 1C, in FIG. 2C, a first filling material 250a can also be first filled in the space between the bottom of the chips 230 and the RDL 220, and then a second filling material 250b is filled between the side wall of the chips 230 and the frames 240. In other words, the first filling material 250a is filled between the bottom (active surface) of the chips 230 and the upper surface of the RDL 220, and the second filling material 250b is filled between the side wall of the chips 230 and the frames 240. The other portions in FIG. 2C are similar to those of FIG. 2B and are therefore not repeated herein.

It can be known from the embodiments above that, a filling adhesive material with low viscosity is filled both between the chips and the frames and between the chips and the RDL as a stress buffer layer such that the stress of each layer is distributed in a gradient. Therefore, stress can be dispersed and not be too concentrated, and the overall reliability of the device can be increased. Moreover, if the coefficient of thermal expansion and the Young's modulus of the filling material are continuously adjusted, then a flexible package may also be potentially developed.

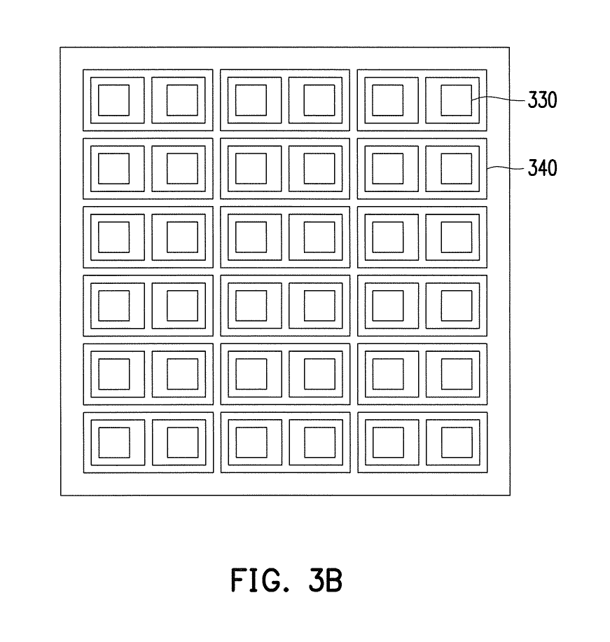

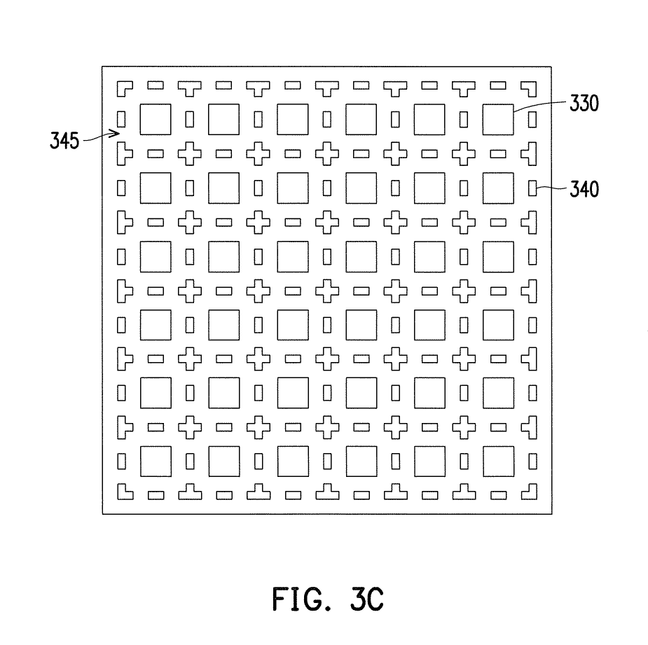

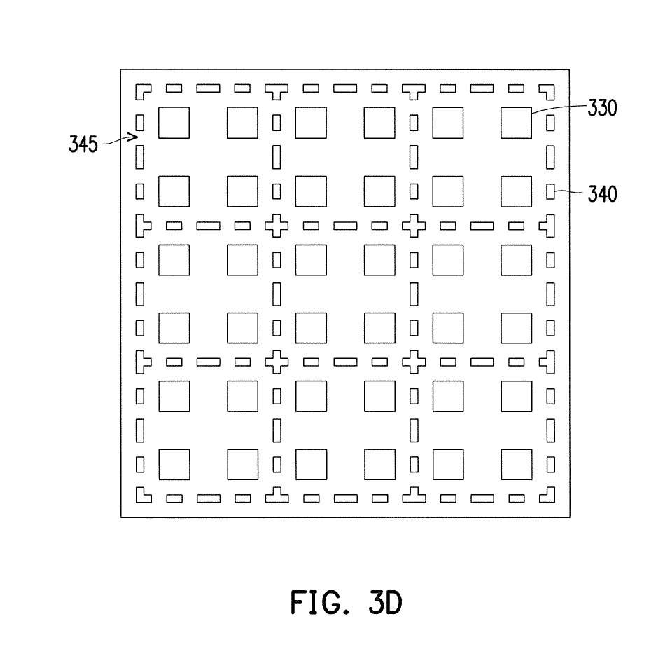

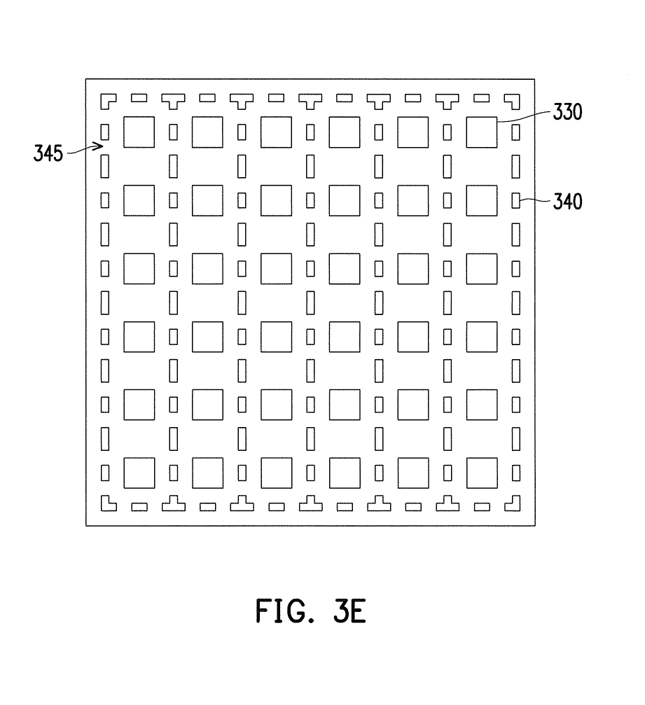

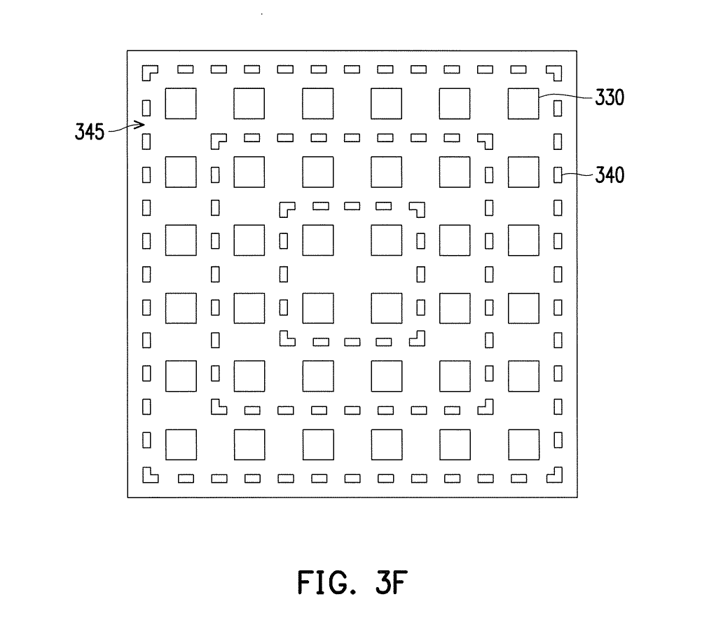

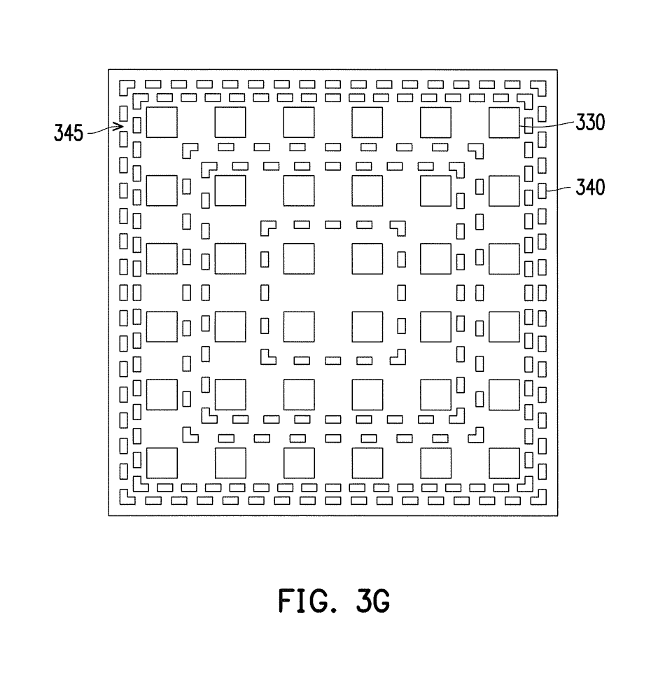

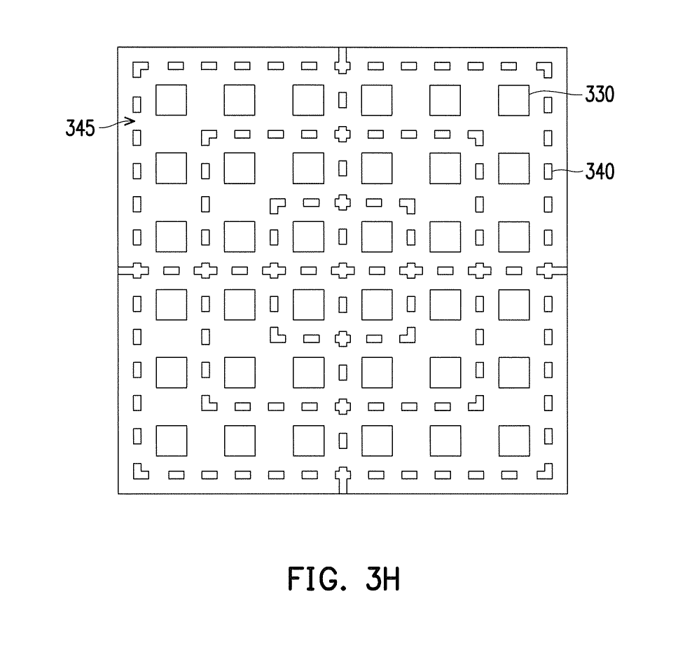

FIG. 3A to FIG. 3H show top views of other possible configurations of the chips and the frames. In FIGS. 3A to 3H, to simply the figures, only the relative positions of chips 330, frames 340, and openings 345 in the frames 340 are shown, and the filling material and the protection layer are omitted. In addition to the configuration of the chips and the frames shown in FIGS. 1A and 2A, many other configurations are possible to effectively disperse thermal stress. Some of the possibilities are shown in FIGS. 3A to 3H. For instance, in FIG. 3A, two chips 330 make up one package unit, and the frames 340 are disposed at four sides of each of the units and connected to one another to form a continuous lattice structure. In FIG. 3B, two chips 330 also make up one package unit, and each of the frames 340 has a double grid shape and surrounds the periphery of each of the chips 330 in each of the package units, but the frames 340 of each of the package units are separated from one another and are not connected.

In FIGS. 3C to 3H, more configurations of the frames 340 are shown, and the common feature thereof is that the frames 340 have at least one opening 345, and the frames 340 surround each of the package units in a non-continuous manner. The openings 345 need to be narrow enough such that the filling material does not flow out of the openings 345 but gas is allowed to escape from the openings 345 to reduce the possibility of air bubbles in the filling material.

In FIG. 3C, the configuration of the frames 340 is substantially similar to the configuration of the frame 140 of FIG. 1A, and the frames 340 are disposed on the peripheral sides of each of the chips 330. However, the continuously connected frame 140 of FIG. 1A is changed to equidistant and equal but discontinuous frames 340 in FIG. 3C. In other words, the continuously connected frame 140 of FIG. 1A is changed to have gaps/openings 345 such that the continuously connected frame structure is changed to a discontinuous frame structure. In FIG. 3D, 4 chips 330 in a 2×2 array make up one package unit, and the frames 340 are equidistant and equal but discontinuous frame structures and disposed on the peripheral sides of each of the units. In FIG. 3E, 6 chips 330 of each column in a vertical arrangement make up one package unit, and the frames 340 are equidistant and equal but discontinuous frame structures and disposed at four sides of each of the units. In FIGS. 3F to 3G, the frames 340 are equidistant and equal but discontinuous frame structures, and are disposed in the manner of a concentric square ring. But in FIG. 3G, the density of the frame structures disposed on the peripheral positions is higher, or the distance between the adjacent frames of the equidistant configuration is smaller. In FIG. 3H, in addition to being disposed in the manner of a concentric square ring, the frames 340 are also disposed in a cross. It can be known from FIGS. 3A to 3H that, the configuration of the frames 340 can be designed based on overall package requirements or stress buffer requirements for a product, and is not limited to the specific forms shown in the embodiments of the present application.

### Manufacturing Method of Chip Package Structure

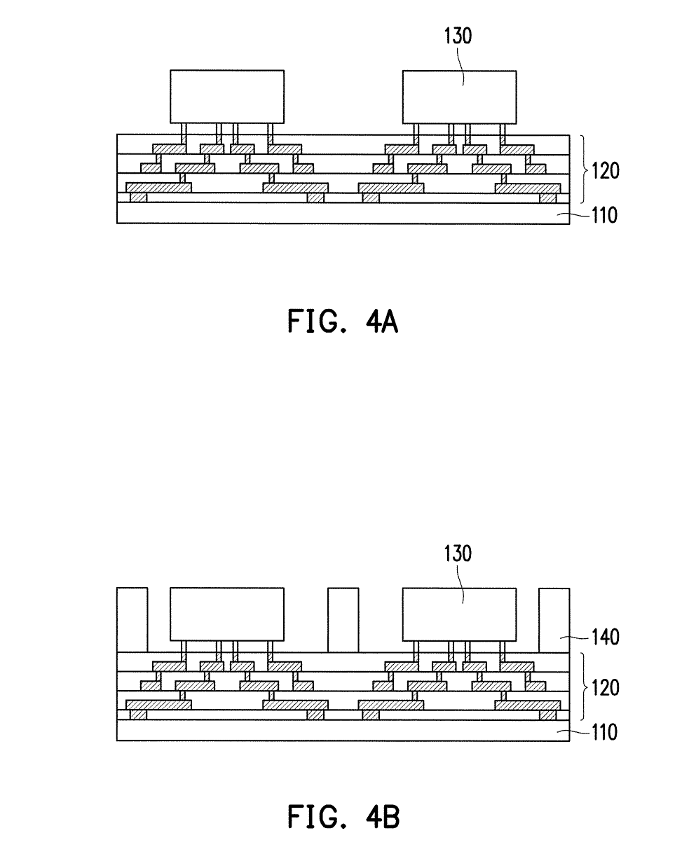

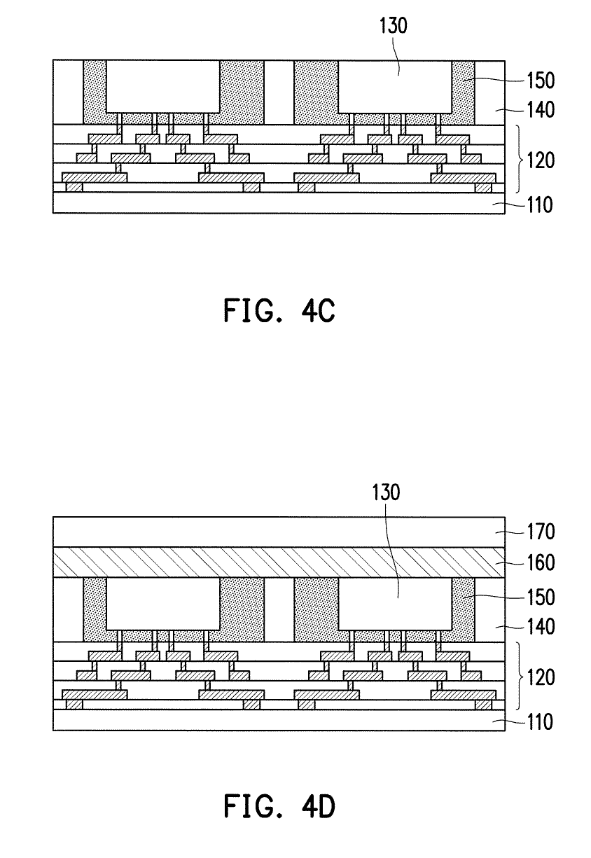

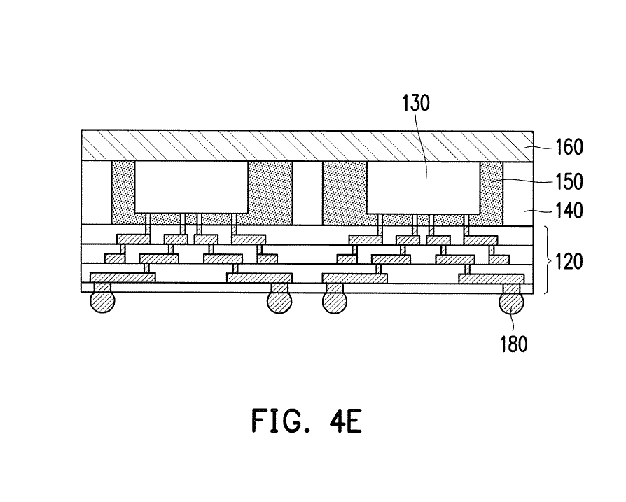

In the following, the manufacturing method of the chip package structure above is described. First, in the case of the chip structure in FIG. 1B, FIGS. 4A to 4E show cross sections of the structure in a manufacturing process of the chip package structure in FIG. 1B. In FIG. 4A, an RDL 120 is formed on a carrier board or a substrate 110. According to an embodiment, the forming of the RDL 120 includes forming a plurality of dielectric layers and a plurality of conductive layers that are alternately stacked in order. The forming method of the RDL 120 can substantially include, for instance, first depositing and then patterning an insulation dielectric layer, forming an opening in the insulation dielectric layer and then filling a metal plug, and then depositing and patterning a metal layer on the insulation layer to form a metal circuit. Next, the steps of forming the insulation layer and the metal layer are repeated as needed to achieve the object of changing the circuit contact positions of the chips 130.

A plurality of contacts is formed on the top-most conductive layer of the resulting RDL 120 and contact pads are formed on the bottom-most conductive layer of the RDL 120. A plurality of chips 130 are disposed on the upper surface of the RDL 120, and then the chips 130 are bonded to the contacts of the RDL 120 such that the chips 130 are electrically connected to the RDL 120 via the contacts on the upper surface of the RDL 120. The method of bonding the chips 130 and the RDL 120 can be, for instance, soldering.

In FIG. 4B, a plurality of frames 140 are formed around the chips 130 such that the frames 140 are located on the upper surface of the RDL 120. As described above, the height of the frames 140 is not particularly limited, and can be lower than, equal to, or higher than the height of the chips 130. When the material of the frames 140 is a thermosetting epoxy resin, the forming method thereof can be, for instance, printing, spraying, or a dry film process, and then a thermosetting step is performed. When the material of the frames 140 is a ceramic or a metal, the frames 140 can also be pre-formed and then placed at the peripheral sides of each of the chips 130.

Next, in FIG. 4C, a filling material 150 is filled in the space between the chips 130 and the frames 140. As described above, the height of the filling material 150 can be lower than or equal to the height of the chips 130 or the frames 140. In the case of the chip package structure in FIG. 1C, a first filling material 150a needs to be filled first in the step. After the space between the bottom of the chips 130 and the RDL 120 is completely filled, a second filling material 150b is filled. The filling method of the filling material 150, the first filling material 150a, and the second filling material 150b can include, for instance, filling a filling adhesive material with low viscosity or a molding material with low viscosity between the frames 140 and the chips 130 via a drop-fill or spraying method, and then performing a curing process to cure the filling adhesive material with low viscosity or the molding material with low viscosity.

In FIG. 4D, a protection layer 160 supported by a support film 170 can be rolled and adhered on the chips 130, the frames 140, and the filling material 150 using, for instance, a roller. In the step, if the chip package structure in FIG. 2A is used, then the protection layer 260 is also filled inside the space 242 between adjacent frames 240.

In FIG. 4E, the support film 170 and the substrate 110 are removed, and then a plurality of bumps 180 is disposed on the side of the RDL 120 opposite to the side on which the chips 130 are disposed, i.e., the bottom surface of the RDL 120. Next, the bumps 180 are bonded and fixed to the RDL 120, and the bumps 180 can be fixed to the RDL 120 via, for instance, an annealing and soldering process, such that the bumps 180 are electrically connected to the RDL 120 via the contact pads on the bottom surface of the RDL 120. At this point, the manufacture of the entire wafer-level chip package structure is largely complete, and a wafer cutting process can be further performed subsequently to cut the wafer-level chip package structure into independent package units along the scribe lines. The Young's modulus of the support film 170 is smaller than the Young's modulus of the protection layer 160 after the package structure is complete. The material of the support film 170 includes a metal, a ceramic, or a thermosetting epoxy resin. The other portions are described in detail in “Chip package structure” above and are therefore not repeated herein.

### Simulation Experiment

Next, a simulation comparison experiment is performed for the warping and peeling issues above.

In the experiment for the wafer-level package structure warping issue, a simulation experiment is performed for a traditional package structure and a package structure similar to that in FIGS. 1A to 1B. In the traditional package structure, the filling material 150 in FIG. 1B is not used, that is, the regions occupied by the frame 140, the filling material 150, and the protection layer 160 in FIG. 1B are occupied by a traditional molding material. In the simulation experiment, the materials used for the protection layer 160 in the traditional package structure and the package structure of FIG. 1B are exemplified by the same epoxy resin, the material used for the filling material 150 in the package structure of FIG. 1B is still an epoxy resin with low viscosity, and to provide the protection layer 160 with thermal stability and low hygroscopicity, a trifunctional epoxy resin containing dicyclopentadiene and naphthalene structures is generally used. In the simulation experiment, the substrate is exemplified by a Corning glass A1 having a thickness of 0.7 mm and a diameter of 370 mm, and the total thickness of the adhesive material on the substrate is 250 μm. The heating temperature is 150° C. and the heating time is 0.5 hours to 2 hours. Based on the thermal stress simulation experiment results, the height difference from the center point to the edge of the substrate of the traditional package structure after warping reaches 9.2 mm, but the height difference of the package structure of FIG. 1B after warping is only 0.8 mm.

In the device reliability experiment, the analysis structure used in thermal warpage analysis is a three-layer RDL, an epoxy molding material is used for packaging, and the chip thickness range is exemplified as 100 μm to 250 μm, and heating is performed at 125° C. for 24 hours to 48 hours. The results show that the side stress of the chips of the traditional package structure reaches 14 MPa, but the side stress of the chips of the package structure similar to that of FIG. 1B is only 1.8 MPa.

Based on the above, in an embodiment of the disclosure, a filling material with low viscosity and lower Young's modulus and lower coefficient of thermal expansion is used to fill the space between the chips and the frames in place of the original molding material with high Young's modulus or a material with high coefficient of thermal expansion, and therefore residual thermal stress can be significantly reduced to alleviate the issue of package warping after thermal cycling and to further alleviate the issue of peeling of the molding material located at a side of the chips. Moreover, the filling material adopts a material with lower viscosity, and therefore the filling process is simple, and production yield can be increased.

Although the disclosure has been described with reference to the above embodiments, it will be apparent to one of the ordinary skill in the art that modifications and variations to the described embodiments may be made without departing from the spirit and scope of the disclosure. Accordingly, the scope of the disclosure will be defined by the attached claims not by the above detailed descriptions.

What is claimed is:

1. A chip package structure, comprising:
a redistribution layer, wherein the redistribution layer has an upper surface;
a chip disposed on the upper surface of the redistribution layer and electrically connected to the redistribution layer;
a frame disposed on the upper surface of the redistribution layer and surrounding the chip;
a filling material disposed on the upper surface of the redistribution layer and located between the frame and the chip; and
a protection layer covering the chip, the frame, and the filling material, wherein a Young's modulus of the filling material is respectively smaller than a Young's modulus of the chip, a Young's modulus of the frame, and a Young's modulus of the protection layer, and a filling thickness of the filling material is at least 1.5 times a thickness of the protection layer.

2. The chip package structure of claim 1, wherein a coefficient of thermal expansion of the filling material is smaller than 30 ppm/° C.

3. The chip package structure of claim 1, wherein a height of an upper surface of the filling material is smaller than or equal to a height of an upper surface of the chip.

4. The chip package structure of claim 1, wherein a coefficient of thermal expansion of the filling material is smaller than a coefficient of thermal expansion of the frame and a coefficient of thermal expansion of the protection layer.

5. The chip package structure of claim 1, wherein the filling material comprises:
a first filling material located between a bottom surface of the chip and the upper surface of the redistribution layer; and
a second filling material located between a side of the chip and the frame.

6. The chip package structure of claim 5, wherein a viscosity of the first filling material is smaller than or equal to a viscosity of the second filling material.

7. The chip package structure of claim 1, wherein a material of the protection layer and the frame independently comprises a metal, a ceramic, or a thermosetting epoxy resin.

8. A chip package structure, comprising:
a redistribution layer, wherein the redistribution layer has an upper surface;
a chip disposed on the upper surface of the redistribution layer and electrically connected to the redistribution layer;
a frame disposed on the upper surface of the redistribution layer and surrounding the chip;
a filling material disposed on the upper surface of the redistribution layer and located between the frame and the chip, wherein a viscosity of the filling material is 2,000 mPa·s to 20,000 mPa·s at 25° C.; and
a protection layer covering the chip, the frame, and the filling material, wherein a Young's modulus of the filling material is respectively smaller than a Young's modulus of the chip, a Young's modulus of the frame, and a Young's modulus of the protection layer.

9. The chip package structure of claim 8, wherein a coefficient of thermal expansion of the filling material is smaller than 30 ppm/° C.

10. The chip package structure of claim 8, wherein a height of an upper surface of the filling material is smaller than or equal to a height of an upper surface of the chip.

11. The chip package structure of claim 8, wherein a coefficient of thermal expansion of the filling material is smaller than a coefficient of thermal expansion of the frame and a coefficient of thermal expansion of the protection layer.

12. The chip package structure of claim 8, wherein the filling material comprises:
a first filling material located between a bottom surface of the chip and the upper surface of the redistribution layer; and
a second filling material located between a side of the chip and the frame.

13. The chip package structure of claim 12, wherein a viscosity of the first filling material is smaller than or equal to a viscosity of the second filling material.

14. The chip package structure of claim 8, wherein a material of the protection layer and the frame independently comprises a metal, a ceramic, or a thermosetting epoxy resin.

15. A manufacturing method of a chip package structure, comprising:
forming a redistribution layer;
bonding a plurality of chips on the redistribution layer;
forming a plurality of frames on the redistribution layer to respectively surround at least one of the chips;
filling a filling material in a space between the frames and the chips;
forming a protection layer on the chips, the frames, and the filling material, wherein a Young's modulus of the filling material is respectively smaller than a Young's modulus of the chips, a Young's modulus of the frames, and a Young's modulus of the protection layer; and
performing a singulation process.

16. The method of claim 15, wherein a filling thickness of the filling material is at least 1.5 times a thickness of the protection layer.

17. The method of claim 15, wherein a coefficient of thermal expansion of the filling material is smaller than 30 ppm/°C.

18. The method of claim 15, wherein a coefficient of thermal expansion of the filling material is smaller than a coefficient of thermal expansion of the frame and a coefficient of thermal expansion of the protection layer.

19. The method of claim 15, wherein a viscosity of the filling material is 2,000 mPa·s to 20,000 mPa·s at 25° C.

20. The method of claim 15, wherein the filling material comprises:
a first filling material located between a bottom surface of the chip and the redistribution layer; and
a second filling material located between a side of the chip and the frame, wherein a viscosity of the first filling material is smaller than or equal to a viscosity of the second filling material.
